(19) United States
(12) Patent Application Publication
(10) Pub. No.: US 2012/0326113 A1
(43) Pub. Date: Dec. 27, 2012

(54) NON-VOLATILE MEMORY ELEMENT AND NON-VOLATILE MEMORY DEVICE EQUIPPED WITH SAME

(76) Inventors: Shinichi Yoneda, Kyoto (JP); Takumi Mikawa, Shiga (JP); Yukio Hayakawa, Kyoto (JP); Takeki Ninomiya, Osaka (JP)

(21) Appl. No.: 13/582,370

(22) PCT Filed: Jun. 9, 2011
(86) PCT No.: PCT/JP2011/003270

§ 371 Date: Aug. 31, 2012

(30) Foreign Application Priority Data
Jun. 10, 2010 (JP) 2010-132885

(51) Int. Cl. H01L 45/00

(52) U.S. Cl. 257/4; 257/E45.001

(57) ABSTRACT

Provided are a non-volatile memory element which can reduce a voltage of an electric pulse required for initial breakdown, and can lessen non-uniformity of a resistance value of the non-volatile memory element, and a non-volatile memory device including the non-volatile memory element. A non-volatile memory element comprises a first electrode (103); a second electrode (105); and a variable resistance layer (104) interposed between the first electrode (103) and the second electrode (105), a resistance value of the variable resistance layer being changeable reversibly in response to an electric signal applied between the first electrode (103) and the second electrode (105); wherein the variable resistance layer (104) includes a first region (106) which is in contact with the first electrode (103) and comprises an oxygen-deficient transition metal oxide and a second region (107) which is in contact with the second electrode (105) and comprises a transition metal oxide having a smaller degree of oxygen deficiency than the first region (106); and wherein the second electrode (105) comprises an alloy including iridium and at least one precious metal having lower Young's modulus than iridium, and a content of iridium is not less than 50 atm %.

### TECHNICAL FIELD

The present invention relates to a variable resistance non-volatile semiconductor memory element, resistance values of which change by application of voltage pulses, and a non-volatile memory device including the variable resistance non-volatile semiconductor memory element.

### BACKGROUND ART

In recent years, with a progress of digital technologies, electronic devices such as portable information devices and information home appliances have been developed to provide higher functionalities. For this reason, demands for an increase in a capacity of a variable resistance element, reduction in a write electric power in the memory element, reduction in write/read time in the memory element, and longer life of the memory element have been increasing.

Under the circumstances in which there are such demands, it is said that there is a limitation on miniaturization of the existing flash memory using a floating gate. In contrast, a variable resistance element (variable resistance memory) including a variable resistance layer as a material of a memory section, can be constructed of a memory element having a simple structure including a variable resistance element. Therefore, it is expected that the variable resistance element can achieve further miniaturization, a higher speed and lower electric consumption.

When the variable resistance material is used as the memory section, its resistance value changes from a higher-resistance value to a lower-resistance value or from a lower-resistance value to a higher-resistance value, for example, by applying an electric pulse. In this case, it is necessary to clearly distinguish binary values which are the lower-resistance value and the higher-resistance value from each other, stably change the resistance value between the lower-resistance value and the higher-resistance value at a higher speed, and preserve the binary values in a non-volatile manner. For the purpose of achievement of the stability of such memory characteristics and miniaturization of the memory element, there have been various proposals in the past.

As one of the proposals, Patent Literature 1 discloses a non-volatile memory element including two electrodes and a variable resistance layer sandwiched between these electrodes, in which one of the electrodes comprises a precious metal material such as platinum (Pt). This non-volatile memory element has a structure in which the variable resistance layer is sandwiched between platinum which is an electrode material which causes resistance change more easily and an electrode material (e.g., tungsten, etc.) which causes resistance change less easily, to enable resistance change to take place in a desired region of the variable resistance layer which is at one electrode side (higher-concentration layer side), thereby enabling the non-volatile memory element to operate stably.

### CITATION LISTS

### Patent Literatures

Patent Literature 1: International Publication No. WO2009/050833

### SUMMARY OF THE INVENTION

### Technical Problem

However, the above stated conventional non-volatile memory element has the following problem.

In a case where a transition metal oxide such as an oxygen-deficient tantalum oxide layer is used as the variable resistance layer, a stable operation is attained by forming a stacked-layer structure in which the variable resistance layer eludes a higher-oxygen-content layer (higher-concentration layer) and a lower-oxygen-content layer (lower-concentration layer). As defined herein, the oxygen-deficient metal oxide refers to a metal oxide which is less in oxygen content than a metal oxide having a stoichiometric composition. When the composition of the above stated tantalum oxide is expressed as TaOₓ, a tantalum oxide having a stoichiometric composition is expressed as TaO_{2.5} (Ta₂O₅). Therefore, the value of x of the oxygen-deficient tantalum oxide is 0<x<2.5. The range of x differs depending on the value of valency of the metal. In general, a metal oxide having a stoichiometric composition exhibits an insulating property, while the oxygen-deficient metal oxide exhibits a semiconductive property.

In the variable resistance layer having the stacked-layer structure including the higher-concentration layer (higher-resistance layer) and the lower-concentration layer (lower-resistance layer) as described above, an initial resistance value in initial application of an electric signal is higher than a resistance value corresponding to a higher-resistance state in normal resistance change. In this state, the resistance change does not occur by applying the electric signal. To attain a resistance changing characteristic, it is necessary to apply an electric pulse to the variable resistance layer in an initial state to form an electric path in the higher-resistance layer (to enable breakdown to occur in the higher-resistance layer). This processing is referred to as initial breakdown. A voltage (initial breakdown voltage) of the electric pulse is higher than a voltage of the electric pulse required to change the variable resistance layer as the memory from the lower-resistance state to the higher-resistance state or from the higher-resistance state to the lower-resistance state. Therefore, there exists a problem that a special circuit for generating such a high voltage is needed. The voltage of the electric pulse required for the initial breakdown could be reduced by thinning the higher-concentration layer of the variable resistance layer. However, thinning the higher-concentration layer of the variable resistance layer is undesirable in view of reliability.

To enable a stable resistance changing phenomenon to occur, it is desired that an electrode material such as platinum which causes resistance change more easily be placed at a higher-resistance layer side, Platinum has a higher thermal expansion coefficient (8.8×10⁻⁶ (degrees C⁻¹)), and lower Young's modulus) (152×10⁹ (N/m²)). Because of these physical properties, platinum is plastically deformed easily due to heat and a mechanical stress and causes hillocks to be formed thereon easily. When the hillocks are formed on the electrode, migration of the electrode to the variable resistance layer takes place, and the electrode material protrudes into the higher-concentration layer, thereby decreasing an effective thickness of the higher-concentration layer of the variable resistance layer. Because of this, non-uniformity of the resistance value of the variable resistance layer tends to occur. In addition, it is presumed that regarding palladium having physical characteristics similar to those of platinum, hillocks are formed thereon easily, and therefore non-uniformity of the resistance value of the variable resistance layer would tend to occur.

The present invention has been developed under the circumstances, and an object of the present invention is to provide a non-volatile memory element which can reduce a voltage of an electric pulse required for initial breakdown, and can lessen non-uniformity of the resistance value of the non-volatile memory element, and a non-volatile memory device including the non-volatile memory element.

### Solution to Problem

To solve above stated problems, according to one aspect of the present invention, a non-volatile memory element comprises a first electrode; a second electrode; and a variable resistance layer interposed between the first electrode and the second electrode, a resistance value of the variable resistance layer being changeable reversibly in response to an electric signal applied between the first electrode and the second electrode; wherein the variable resistance layer includes a first region which is in contact with the first electrode and comprises an oxygen-deficient transition metal oxide and a second region which is in contact with the second electrode and comprises a transition metal oxide having a smaller degree of oxygen deficiency than the first region; and wherein the second electrode comprises an alloy including iridium and at least one precious metal having lower Young's modulus than iridium, and a content of iridium is not less than 50 atm %.

The alloy may allow a voltage of an electric pulse required for initial breakdown of the variable resistance layer to be reduced, and non-uniformity of the resistance value of non-volatile memory element to be lessened.

The second electrode may comprise an alloy including iridium and platinum, and a content of platinum is not less than 20 atm % and not greater than 50 atm %.

The second electrode may comprise an alloy including iridium and palladium, and a content of palladium is not less than 20 atm % and not greater than 50 atm %.

The variable resistance layer may have a stacked-layer structure in which the transition metal oxide constituting the variable resistance layer is composed of a plurality of layers which are different in oxygen concentration.

According to another aspect of the present invention, a non-volatile semiconductor device comprises a memory array including: a plurality of first wires formed on a semiconductor substrate such that the plurality of first wires extend in parallel with each other; a plurality of second wires formed above the plurality of first wires such that the plurality of second wires extend in parallel with each other within a plane parallel to a main surface of the semiconductor substrate and three-dimensionally cross the plurality of first wires, respectively; and non-volatile memory elements provided to respectively correspond to three-dimensional cross points of the plurality of first wires and the plurality of second wires; wherein each of the non-volatile memory elements includes: a first electrode; a second electrode; and a variable resistance layer interposed between the first electrode and the second electrode, a resistance value of the variable resistance layer being changeable reversibly in response to an electric signal applied between the first electrode and the second electrode; wherein the variable resistance layer includes a first region which is in contact with the first electrode and comprises an oxygen-deficient transition metal oxide and a second region which is in contact with the second electrode and comprises an oxygen-deficient transition metal oxide having a smaller degree of oxygen deficiency than the first region; and wherein the second electrode comprises an alloy including iridium and at least one precious metal having lower Young's modulus than iridium, and a content of iridium is not less than 50 atm %.

According to another aspect of the present invention, a non-volatile semiconductor device comprises a plurality of first wires formed on a semiconductor substrate such that the plurality of first wires extend in parallel with each other; a plurality of second wires formed above the plurality of first wires such that the plurality of second wires extend in parallel with each other within a plane parallel to a main surface of the semiconductor substrate and three-dimensionally cross the plurality of first wires, respectively; a plurality of third wires arranged in parallel with the plurality of first wires or the plurality of second wires such that the plurality of third wires extend in parallel with each other; a plurality of transistors provided to respectively correspond to three-dimensional cross-points of the first wires and the second wires; and a plurality of non-volatile memory elements provided to respectively correspond to the transistors in a one-to-one correspondence; wherein each of the non-volatile memory elements includes a first electrode; a second electrode; and a variable resistance layer interposed between the first electrode and the second electrode, a resistance value of the variable resistance layer being changeable reversibly in response to an electric signal applied between a corresponding one of the first wires and a corresponding one of the third wires and thereby applied between the first electrode and the second electrode via a corresponding one of the transistors; one of the first electrode and the second electrode of the non-volatile memory element is connected to one of a source and a drain of a corresponding one of the transistors; a gate of each of the plurality of transistors is connected to a corresponding one of the first wires; the other of the first electrode and the second electrode of the non-volatile memory element is connected to one of a corresponding one of the second wires and a corresponding one of the third wires; the other of the source and the drain of the transistor is connected to the other of the corresponding one of the second wires and the corresponding one of the third wires; the variable resistance layer includes a first region which is in contact with the first electrode and comprises an oxygen-deficient transition metal oxide and a second region which is in contact with the second electrode and comprises an oxygen-deficient transition metal oxide having a smaller degree of oxygen deficiency than the first region; and the second electrode comprises an alloy including iridium and at least one precious metal having lower Young's modulus than iridium, and a content of iridium is not less than 50 atm %.

The above and further objects, features and advantages of the present invention will more fully be apparent from the following detailed description of preferred embodiments with accompanying drawings.

### Advantageous Effects of the Invention

The present invention has the above described description, and has advantages that it is possible to reduce a voltage of an electric pulse required for initial breakdown, and lessen non-uniformity of the resistance value of the non-volatile memory element.

### BRIEF DESCRIPTION OF THE DRAWINGS

FIG. 1 is a cross-sectional view showing an exemplary configuration of a non-volatile memory element according to Embodiment 1 of the present invention.

FIG. 2 is a graph showing a calculated value of a platinum content with respect to a ratio of a DC power applied to a target in a case where an iridium alloy layer including platinum is deposited by a simultaneous discharge sputtering method.

FIG. 3 is a graph showing a change in an initial resistance value and a change in an initial breakdown voltage with respect to a change in a platinum content of a second electrode layer in a non-volatile memory element according to Embodiment 1 of the present invention.

FIG. 4A is a cross-sectional view showing a region in the vicinity of an electrode in a case where a platinum electrode layer is used in the non-volatile memory element.

FIG. 4B is a cross-sectional view showing a region in the vicinity of an electrode in a case where a palladium electrode is used in the non-volatile memory element.

FIG. 5A is a view showing a sketch of the cross-sectional view of FIG. 4A.

FIG. 5B is a view showing a sketch of the cross-sectional view of FIG. 4B.

FIG. 6A is a graph showing evaluation results of initial resistance values corresponding to a platinum electrode, a palladium electrode, and an iridium electrode, respectively, in the non-volatile memory element according to Embodiment 1 of the present invention.

FIG. 6B is a graph showing evaluation results of initial breakdown voltages corresponding to the platinum electrode, the palladium electrode, and the iridium electrode, respectively, in the non-volatile memory element according to Embodiment 1 of the present invention.

FIG. 7 is a graph showing the relationship between a resistance value of a variable resistance layer and the number of times of pulse application in the non-volatile memory element according to Embodiment 1 of the present invention.

FIG. 8 is a graph showing a change in the resistance value of the variable resistance layer with respect to the platinum content of the second electrode layer.

FIG. 9 is a view showing an exemplary operation in a case where data is written to the non-volatile memory element according to Embodiment 1 of the present invention.

FIG. 10 is a view showing an exemplary operation in a case where data is read from the non-volatile memory element according to Embodiment 1 of the present invention.

FIG. 11 is a cross-sectional view showing another exemplary configuration of the non-volatile memory element according to Embodiment 1 of the present invention.

FIG. 12 is a block diagram showing the configuration of a non-volatile memory device incorporating the non-volatile memory element according to Embodiment 1 of the present invention.

FIG. 13 is a perspective view showing the configuration (configuration of 4 bits) of a part A in the non-volatile memory device of FIG. 12.

FIG. 14 is a cross-sectional view showing the configuration of a non-volatile memory element in a first application example of the non-volatile memory device of FIG. 12.

FIG. 15 is a perspective view showing the configuration of a memory array in a multi-layer structure of the first application example of the non-volatile memory device of FIG. 12.

FIG. 16 is a block diagram showing the configuration of a second application example of the non-volatile memory device incorporating the non-volatile memory element according to Embodiment 1 of the present invention.

FIG. 17 is a cross-sectional view showing the configuration (configuration of 2 bits) of a part C in the non-volatile memory device of FIG. 16.

FIG. 18A is a graph showing an evaluation result of a cell current flowing through the non-volatile memory element in a case where a ratio between iridium and platinum in the second electrode layer is 100:0 in the non-volatile memory element of the non-volatile memory device in the second application example.

FIG. 18B is a graph showing an evaluation result of the cell current flowing through the non-volatile memory element in a case where the ratio between iridium and platinum in the second electrode layer is 80:20 in the non-volatile memory element of the non-volatile memory device in the second application example.

FIG. 18C is a graph showing an evaluation result of the cell current flowing through the non-volatile memory element in a case where the ratio between iridium and platinum in the second electrode layer is 70:30 in the non-volatile memory element of the non-volatile memory device in the second application example.

FIG. 19A is a graph showing an evaluation result of the cell current flowing through the non-volatile memory element in a case where the ratio between iridium and platinum in the second electrode layer is 60:40 in the non-volatile memory element of the non-volatile memory device in the second application example.

FIG. 19B is a graph showing an evaluation result of the cell current flowing through the non-volatile memory element in a case where the ratio between iridium and platinum in the second electrode layer is 50:50 in the non-volatile memory element of the non-volatile memory device in the second application example.

FIG. 19C is a graph showing an evaluation result of the cell current flowing through the non-volatile memory element in a case where the ratio between iridium and platinum in the second electrode layer is 40:60 in the non-volatile memory element of the non-volatile memory device in the second application example.

FIG. 20 is a graph showing a change in the cell current with respect to a change in the platinum content of the second electrode layer, in the non-volatile memory element of the non-volatile memory device in the second application example.

### DESCRIPTION OF THE EMBODIMENTS

Hereinafter, embodiments of the present invention will be described with reference to the drawings. Throughout the drawings, the same constituents are designated by the same reference symbols and will not be described repetitively in some cases.

### Embodiment 1

[Configuration of Non-Volatile Memory Element]

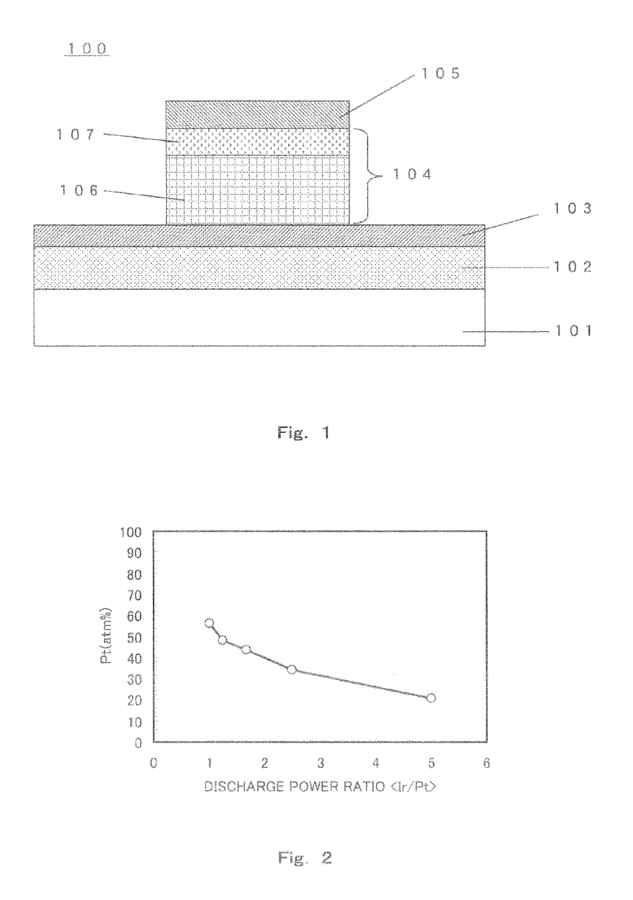

FIG. 1 is a cross-sectional view showing an exemplary configuration of a non-volatile memory element according to Embodiment 1 of the present invention.

As shown in FIG. 1, a non-volatile memory element 100 includes a substrate 101, an oxide layer 102 which is an insulating layer formed on the substrate 101, a first electrode layer (first electrode) 103 formed on the oxide layer 102, a second electrode layer (second electrode) 105, a variable resistance layer 104 (stacked-layer structure of a first transition metal oxide layer 106 and a second transition metal oxide layer 107 as will be described later) sandwiched between the first electrode layer 103 and the second electrode layer 105.

When the non-volatile memory element 100 is driven, a voltage (electric signal) satisfying a specified condition is applied between the first electrode layer 103 and the second electrode layer 105 by an electric power supply provided outside. According to the direction (polarity of voltage) in which the voltage is applied, the resistance value of the variable resistance layer 104 of the non-volatile memory element 100 increases or decreases. For example, when a pulse voltage which is greater than a predetermined threshold voltage is applied, the resistance value of the variable resistance layer 104 increases or decreases. On the other hand, when a pulse voltage which is smaller than the predetermined threshold voltage is applied, the resistance value of the variable resistance layer 104 does not change.

The variable resistance layer 104 comprises a transition metal oxide. The variable resistance layer 104 has a stacked-layer structure in which a first region 106 (first transition metal oxide layer) which is in contact with the first electrode layer 103 and comprises an oxygen-deficient transition metal oxide, and a second region 107 (second transition metal oxide layer) which is in contact with the second electrode layer 105 and comprises a transition metal oxide which is higher in oxygen content than that of the first region 106, are stacked together. In the present embodiment, the transition metal oxide comprises a tantalum oxide. The tantalum oxide (first tantalum oxide) of the first region 106 satisfies 0<x<2.5 when the tantalum oxide is expressed as TaOₓ. The tantalum oxide (second tantalum oxide) of the second region 107 satisfies x<y when the tantalum oxide is expressed as TaO_{y}. To enable the variable resistance element to operate stably, it is preferable that TaOₓ satisfies 0.8≦x≦1.9 and TaO_{y} satisfies 2.1≦y≦2.5.

The oxygen-deficient transition metal oxide is defined as an oxide which is less in oxygen content (atom ratio: ratio of oxygen atom number to total atom number) than an oxide having a stoichiometric composition. Typically, the oxide having a stoichiometric composition is an insulator or has a very high resistance value.

The oxygen content of the second region 107 comprising the second tantalum oxide is higher than the oxygen content of the first region 106 comprising the first tantalum oxide. For example, the oxygen content of Ta₂O₅ having a stoichiometric composition is the ratio of oxygen with respect to a total atom number (O/(Ta+O)) and is 71.4%. Therefore, the oxygen content of the oxygen-deficient tantalum oxide is greater than 0% and less than 71.4%. The resistance value of the transition metal oxide used in the variable resistance element is higher as the oxygen content is greater.

In other words, it may be said that the degree of oxygen deficiency of the second region 107 is less than the degree of oxygen deficiency of the first region 106.

The degree of oxygen deficiency is defined as a ratio of deficient oxygen with respect to the amount of oxygen of the oxide having a stoichiometric composition, in each transition metal. For example, in a case where the transition metal is tantalum (Ta), the composition of the oxide having a stoichiometric composition is Ta₂O₅ and can be expressed as TaO_{2.5}. The degree of oxygen deficiency of TaO_{2.5} is 0%. For example, the degree of oxygen deficiency of the oxygen-deficient tantalum oxide having a composition of TaO_{1.5} is the degree of oxygen deficiency=(2.5−1.5)/2.5=40%.

A metal constituting the first variable resistance layer and a metal constituting the second variable resistance layer may be a transition metal other than tantalum. As the transition metal, tantalum (Ta), titanium (Ti), hafnium (Hf), zirconium (Zr), niobium (Nb), tungsten (W), etc., may be used. Since the transition metal can have a plurality of oxidized states, different resistance states can be realized by a redox reaction. For example, in the case of using the tantalum oxide, it can be confirmed that the resistance value of the variable resistance layer 104 can change stably at a higher speed, if x is not less than 0.8 and not greater than 1.9 when the composition of the first tantalum oxide layer constituting the first region 106 is TaOₓ, and if y is greater in value than x when the composition of the second tantalum oxide layer constituting the second region 107 is TaO_{y}. In this case, the thickness of the second tantalum oxide layer is preferably not less than 1 nm and not greater than 8 nm. In the case of using the hafnium oxide, it can be confirmed that the resistance value of the variable resistance layer 104 can change stably at a higher speed, if x is not less than 0.9 and not greater than 1.6 when the composition of a first hafnium oxide layer constituting the first region 106 is HfOₓ, and if y is greater in value than x when the composition of a second hafnium oxide layer constituting the second region 107 is HfO_{y}. In this case, the thickness of the second hafnium oxide layer is preferably not less than 3 nm and not greater than 4 nm. In the case of using the zirconium oxide, it can be confirmed that the resistance value of the variable resistance layer 104 can change stably at a higher speed, if x is not less than 0.9 and not greater than 1.4 when the composition of a first zirconium oxide layer constituting the first region 106 is ZrOₓ, and if y is greater in value than x when the composition of a second zirconium oxide layer constituting the second region 107 is ZrO_{y}. In this case, the thickness of the second zirconium oxide layer is preferably not less than 1 nm and not greater than 5 nm. By forming the variable resistance layer 104 having the stacked-layer structure including the second region (second transition metal oxide layer) 107 having a higher resistance and being thinner and the first region (first transition metal oxide layer) 106 having a lower resistance and being thicker, a greater portion of the voltage applied to the variable resistance element is fed to the second region having a higher resistance, which facilitates the redox reaction taking place in the second region 107.

The first transition metal constituting the first region 106 and the second transition metal constituting the second region 107 may be different materials. In this case, the degree of oxygen deficiency of the second region 107 is preferably less than the degree of oxygen deficiency of the first region 106. That is, the second region 107 preferably has a higher resistance than the first region 106. In this configuration, a greater portion of the voltage applied between the first electrode 103 and the second electrode 105 is fed to the second region 107 when resistance change occurs, which facilitates the redox reaction taking place in the second region 107. When the first transition metal and the second transition metal are different materials, the standard electrode potential of the second transition metal is preferably lower than the standard electrode potential of the first transition metal. A resistance changing phenomenon may take place in such a manner that the redox reaction proceeds in a minute filament formed in the second region 107 having a higher resistance, and its resistance value changes. For example, when the oxygen-deficient tantalum oxide is used for the first region 106 and a titanium oxide (TiO₂) is used for the second region 107, a stable resistance changing operation is attained. Titanium (standard electrode potential=−1.63 eV) is lower in standard electrode potential than tantalum (standard electrode potential=−0.6 eV). When the value of the standard electrode potential is greater, the corresponding material is oxidized less easily. If an oxide of a metal having a lower standard electrode potential than that of the first region 106 is disposed in the second region 107, the redox reaction takes place more easily in the second region 107.

As the substrate 101, a silicon mono-crystal substrate or a semiconductor substrate is used. However, the substrate 101 is not limited to these. The oxide layer 102 is not particularly limited so long as it serves as an insulating layer, but may be, for example, a silicon oxide layer (SiO₂), etc. Since the variable resistance layer 104 (first region 106) can be formed at a relatively low substrate temperature, it can be formed on a resin material, or the like.

The second electrode layer 105 which is in contact with the second region 107 smaller in the degree of oxygen deficiency, in the variable resistance layer 104, comprises an alloy (alloy including Iridium as a major component) including iridium (Ir) and at least one precious metal (Pt, Pd, Ag, Cu, Au, Rh, Ru, platinum (Pt) in the present embodiment) having lower Young's modulus than iridium (Ir). Such an alloy can reduce the voltage of the electric pulse required for initial breakdown of the variable resistance layer 104 and can lessen non-uniformity of the resistance value of the non-volatile memory element 100, as will be described later. One or two precious metals may be combined with iridium so long as its Young's modulus is lower than that of iridium. That is, an alloy including iridium as a major component and two or more elements is used as the second electrode layer 105. The electrode material of the first electrode layer 103 is not particularly limited. For example, the electrode material may be, for example, W, Ni, Ta, Ti, Al, TaN, etc. (in the present embodiment, tantalum nitride (TaN)). The standard electrode potential of the electrode material of the first electrode layer 103 is desirably lower than the standard electrode potential of the electrode material of the second electrode layer 105. With such a configuration, the resistance changing phenomenon takes place in a portion of the variable resistance layer in the vicinity of the second electrode layer 105. Thus, more stable resistance changing characteristics are attained.

In accordance with this configuration, since the electrode (second electrode layer 105) which is present closer to a portion of the variable resistance layer 104 where the resistance change takes place comprises the iridium alloy including platinum or the like, the voltage of the electric pulse required for the initial breakdown can be reduced, and non-uniformity of the resistance value between the non-volatile memory elements can be lessened.

In specification and claims, “the second electrode (second electrode layer 105) comprises the alloy including iridium and at least one precious metal having lower Young's modulus than iridium” means that the alloy may be added with some elements to improve its characteristics, etc., so long as that alloy can reduce the voltage of the electric pulse required for the initial breakdown of the variable resistance layer 104, and lessen non-uniformity of the resistance value of the non-volatile memory element 100. The addition of the elements to improve its characteristics, etc. is known to those skilled in the art, and may be performed, of course. Also, of course, the alloy of the second electrode layer 105 may contain some impurities other than iridium and another precious metals. Needless to say, such an alloy may be included in the scope of the present invention so long as that alloy can reduce the voltage of the electric pulse required for the initial breakdown, and lessen non-uniformity of the resistance value of the non-volatile memory element 100. The same applies to the first electrode (first electrode layer 103) and the variable resistance layer 104.

[Resistance Changing Phenomenon and Standard Electrode Potential]

Hereinafter, the resistance changing phenomenon taking place in the variable resistance layer will be described. It is presumed that the resistance changing phenomenon taking place in the variable resistance layer having a structure in which the transition metal oxide is sandwiched between the two electrodes is attributed to the redox reaction of the tantalum oxide constituting the higher-concentration layer (second region 107) in the vicinity of an interface between the variable resistance layer and the electrode layer as represented by the following formula:

2TaO₂+O₂⁻→Ta₂O₅+2e⁻

When a negative voltage is applied to the electrode, electrons are implanted to allow a reduction reaction to proceed, resulting in a state in which TaO₂ is present in the portion of the variable resistance layer in the vicinity of the electrode. This could allow a lower-resistance state to be formed. On the other hand, when a positive voltage is applied to the electrode, oxygen ions migrate to allow an oxidization reaction to proceed, resulting in a state in which Ta₂O₅ is present in the portion of the variable resistance layer in the vicinity of the electrode. This could allow a higher-resistance state to be formed. The above stated resistance phenomenon could take place in a minute electric path formed in the higher-concentration layer rather than the entire surface of the interface between the electrode and the variable resistance layer.

To enable the redox reaction represented by the above formula to proceed efficiently, it is essential that the standard electrode potential of the material used for the electrode layer (second electrode layer 105) which is closer to the portion where the resistance changing phenomenon is caused to take place is higher than that of the metal (in the present embodiment Ta) constituting the variable resistance layer. When platinum (Pt) is used for the second electrode layer 105, the standard electrode potential of Ta and the standard electrode potential of platinum are −0.6(V) and 1.19(V), respectively, and therefore there is an electric potential difference of 1V or greater. Therefore, the above stated reaction could proceed efficiently.

In general, the standard electrode potential is used as one indicator indicating that the corresponding material is oxidized less easily. If the value of the standard electrode potential is greater, the corresponding material is oxidized less easily, whereas if the value of the standard electrode potential is smaller, the corresponding material is oxidized more easily. If the standard electrode potential of the electrode is higher than the standard electrode potential of the variable resistance layer and its difference is greater, the resistance change easily takes place more easily in the variable resistance layer side, and the resistance change takes place less easily as the difference is smaller, the resistance change takes place less easily. From this, it is presumed that the degree of easiness of oxidization of metal constituting the variable resistance layer has an important role in a mechanism of the resistance changing phenomenon. In view of this, precious metal elements such as platinum, palladium, iridium, etc., which are higher in standard electrode potential, are effectively used for the electrode material which is closer to the portion (higher-concentration layer) of the variable resistance layer where the resistance changing phenomenon is caused to take place.

[Manufacturing Method of Non-Volatile Memory Element]

Next, a manufacturing method of the non-volatile memory element 100 of the present embodiment will be described.

In the present embodiment, the variable resistance layer 104 has a stacked-layer structure in which the transition metal oxide constituting the variable resistance layer 104 comprises a plurality of layers (the first region 106 and the second region 107) which are different in oxygen concentration.

Initially, on the substrate 101, the oxide layer (insulating layer comprising SiO₂) having a thickness of, for example, 200 nm, is deposited, by a thermal oxidization method or a CVD method. Then, as the first electrode layer 103, a TaN layer having a thickness of, for example, 100 nm, is formed on the oxide layer 102.

Then, on the first electrode layer 103, a first tantalum oxide layer is deposited as the variable resistance layer 104 (first region 106). The thickness of the first tantalum oxide layer is, for example, about 20 to 100 nm. The variable resistance layer is deposited by, for example, a reactive RF sputtering method using a Ta target. At this time, the oxygen-deficient Ta oxide layer can be deposited by controlling the oxygen content of the Ta oxide based on an oxygen flow ratio. The variable resistance layer may be deposited by a sputtering method which does not use reactive gas such as O₂ and uses the tantalum oxide as a target.

Then, the first tantalum oxide layer is oxidized to form the second tantalum oxide layer having a thickness of 2 to 12 nm on an uppermost layer as the second region 107 having a higher oxygen content than the first tantalum oxide layer. Finally, on the variable resistance layer 104, as the second electrode layer 105, for example, an iridium alloy layer including platinum having a thickness of 50 nm, is deposited by a DC sputtering method. Simultaneous sputtering may be performed using a target comprising iridium and a target comprising platinum and a target comprising platinum, or sputtering may be performed using a target comprising an alloy of iridium and platinum.

As described above, since the first region 106 having a lower oxygen content and the second region 107 having a higher oxygen content are formed individually as the variable resistance layer 104, it is possible to form the non-volatile memory element 100 which performs the resistance changing operation stably.

[Composition Control of Iridium-Platinum Alloy Electrode Layer]

An iridium alloy layer including platinum will be described. The iridium alloy layer including platinum is deposited by a DC-sputtering method by simultaneous discharge using iridium and platinum. For example, during deposition, the degree of vacuum is set to 1.0 Pa, a DC power applied is set to 50 to 300 W for each of the iridium target and the platinum target, an Ar flow rate is set to 10 sccm, and a deposition time is set to 20 minutes. FIG. 2 is a graph showing a calculated value of a platinum content (atm %) with respect to a ratio of the DC power applied to each target. As shown in FIG. 2, the content ratio between iridium and platinum can be controlled by adjusting the power applied to each target. The manufacturing method of the second electrode layer 105 using the iridium-platinum alloy as described above can be controlled to attain a desired platinum content by controlling a power ratio of each target.

The second electrode layer 105 can be deposited by the DC-sputtering method using the iridium-platinum alloy target. In this case, since the content ratio between iridium and platinum is determined by the content ratio of the target itself, it is possible to suppress non-uniformity of the content ratio due to non-uniformity of equipment parameters during the DC-sputtering, as compared to the deposition method of the second electrode layer 105 by the simultaneous discharge sputtering method using the individual targets as described above. Note that in this case, the platinum content cannot be controlled based on the DC power ratio.

As used in the specification and claims, “alloy” may include a configuration in which iridium and another precious metal such as platinum are formed into an electrode comprising “alloy” by mixing iridium and another precious metal such as platinum by sputtering during formation of the electrode, on the substrate 101 (second oxide layer 102), as well as a configuration in which an electrode is formed to comprise “alloy” pre-produced by iridium and another precious metal such as platinum, on the substrate 101 (second oxide layer 102) as described above.

[Initial Resistance Value and Initial Breakdown Voltage of Non-Volatile Memory Element]

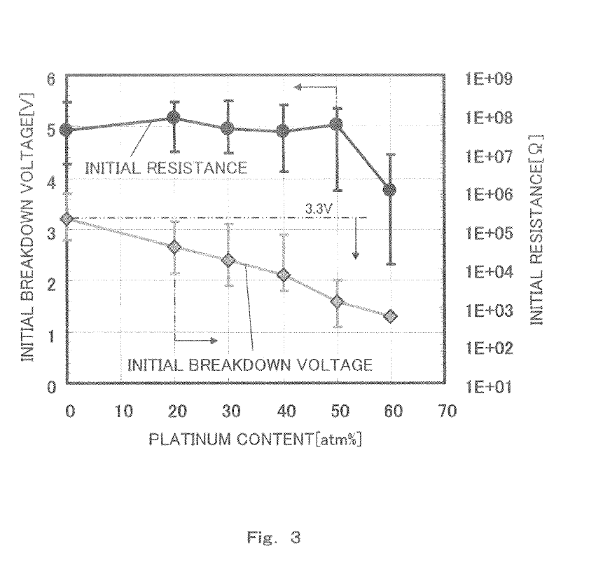

Next, the relationship between the initial resistance value and the platinum content of the second electrode layer 105 in the non-volatile memory element 100 of the present embodiment will be described. FIG. 3 is a graph showing a change in the initial resistance value and a change in the initial breakdown voltage with respect to a change in the platinum content of the second electrode layer in the non-volatile memory element according to Embodiment 1 of the present invention. FIG. 3 shows a change in the initial resistance value and a change in the initial breakdown voltage with respect to a change in the platinum content of the second electrode layer 105 in a case where the size of the electrode of the second electrode layer 105 is 0.5 μm square (area is 0.25 μm²). It can be seen that when the platinum content of the second electrode layer is 60 atm %, the initial breakdown voltage is low, but the initial resistance value is low and has great non-uniformity. It can be understood that when the platinum content of the second electrode layer is 0 atm %, i.e., the second electrode layer comprises iridium which is simple substance, the initial resistance value is high and stable without non-uniformity, but the initial breakdown voltage is as high as about 3.3V and has non-uniformity. From this, it can be understood that this voltage does not satisfy a voltage which is not greater than 3.3V used as general electric power voltage source and required in many circuits.

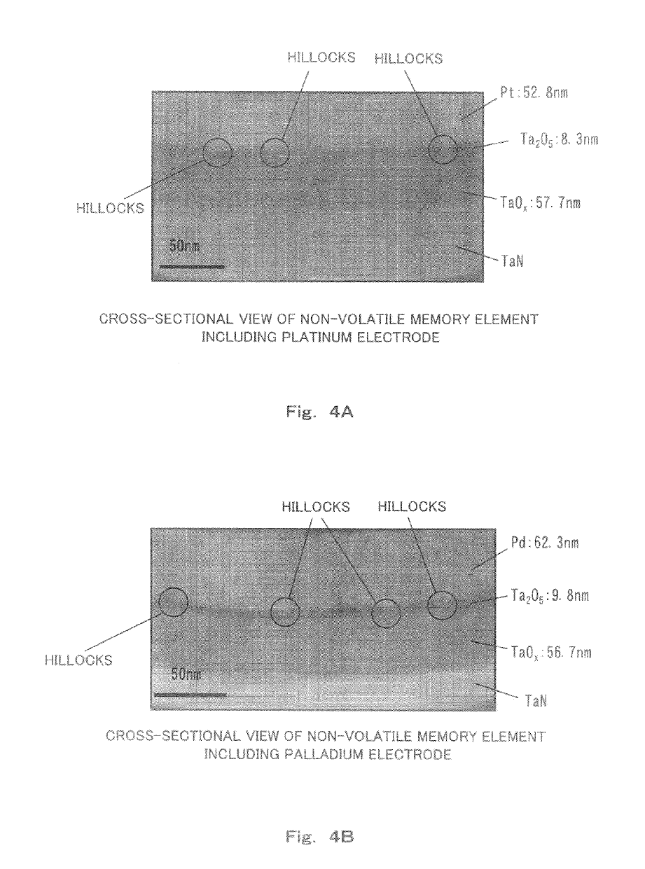

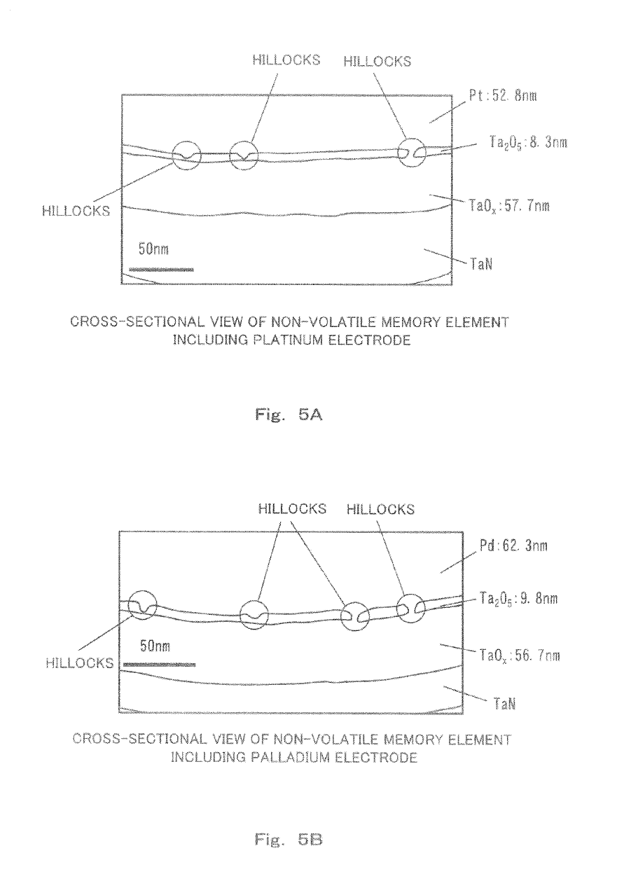

It is presumed that the above is due to a difference in physical characteristics (thermal expansion coefficient and Young's modulus) between platinum and iridium. The thermal expansion coefficient of platinum is high and 8.8×10⁻⁶ (degrees C⁻¹) which is higher than 6.4×10⁻⁶ (degrees C⁻¹) of iridium. The Young's modulus of platinum is low and 152×10⁹ (N/m²) which is lower than 529×10⁹ (N/m²) of iridium. Because of these physical characteristics, platinum is plastically deformed and causes hillocks more easily than iridium, due to heat and a mechanical stress. FIG. 4A is a cross-sectional view showing a region in the vicinity of the electrode in a case where the platinum electrode layer is used in the non-volatile memory element and FIG. 4B is a cross-sectional view showing a region in the vicinity of the electrode in a case where the palladium electrode is used in the non-volatile memory element. FIG. 4A shows the cross-section in the case of using the platinum electrode, while FIG. 4B shows the cross-section in the case of using the palladium electrode. FIG. 5A is a view showing a sketch of the cross-sectional view of FIG. 4A and FIG. 5B is a view showing a sketch of the cross-sectional view of FIG. 4B. As shown in FIGS. 4A and 5A, in the case of using platinum as the electrode, hillocks protrude into the higher-concentration layer (Ta₂O₅) of the variable resistance layer (within circles in FIGS. 4A and 5A). When the hillocks are formed on the electrode, migration of the electrode to the variable resistance layer takes place, thereby decreasing an effective thickness of the higher-concentration layer of the variable resistance layer. Because of this, non-uniformity of resistance value tends to occur. In addition, regarding palladium having physical characteristics (thermal expansion coefficient and Young's modulus have similar values) similar to those of platinum, hillocks are formed easily as shown in FIGS. 4B and 5B, and non-uniformity of resistance value would tend to occur.

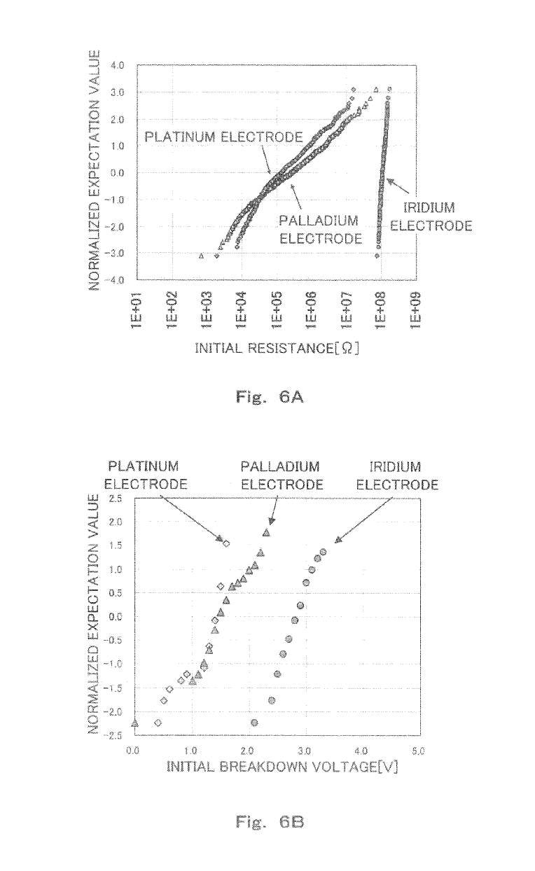

FIG. 6A is a graph showing evaluation results of non-uniformity of the initial resistance value in the cases where the platinum electrode, the palladium electrode, and the iridium electrode are used, respectively, and FIG. 6B is a graph showing evaluation results of non-uniformity of the initial breakdown voltage in the cases where the platinum electrode, the palladium electrode, and the iridium electrode are used, respectively. FIG. 6A shows the evaluation results of the initial resistance value and FIG. 6B shows the evaluation result of the initial breakdown voltage. As can be seen from FIG. 6A, there is great non-uniformity (inclination with respect to a vertical direction is great) of the initial resistance value in the case of the platinum electrode and in the case of the palladium electrode, but there is small non-uniformity (inclination with respect to the vertical direction is small) of the resistance value in the case of the iridium electrode. As can be seen from FIG. 6B, the initial breakdown voltages are all lower in the case of the palladium electrode, but are all higher than those of the palladium electrode in the case of the iridium electrode.

From the above findings, in the present invention, the electrode comprising the alloy of platinum or palladium and iridium is used to achieve an advantage achieved by using the platinum electrode or the palladium electrode (the initial breakdown voltage can be reduced) and an advantage achieved by using the iridium electrode (non-uniformity of the initial resistance value can be lessened).

By adding to the precious metal such as platinum, iridium having higher Young's modulus (higher stiffness) than the precious metal such as platinum, as the electrode material of the second electrode layer 105, the Young's modulus of the entire electrode increases (thermal expansion coefficient decreases), and a mechanical strength of the entire electrode can be enhanced. Therefore, formation of the hillocks on the second electrode layer 105 can be suppressed. In addition, since iridium having a high electric conductivity and being usable as an electrode material in a simple substance state, is added to another precious metal such as platinum having a high electric conductivity, the entire electrode can attain a high electric conductivity. Furthermore, since iridium having in a simple substance state a high standard electrode potential which is required to enable the variable resistance layer comprising the oxygen-deficient transition metal to change its resistance easily, is added to another precious metal such as platinum having a high standard electrode potential, the entire electrode can attain a high standard electrode potential. Since the advantage achieved by addition of iridium is enhancement of the mechanical strength, it is obvious that two or more precious metals may be combined with iridium to form the alloy. From the above, by forming the alloy of iridium and at least one precious metal having lower Young's modulus than iridium, it becomes possible to attain the electrode material which allows the resistance change to occur easily and has a higher mechanical strength.

As shown in FIG. 3, by setting the platinum content of the second electrode layer 105 to 50 atm % or less, the initial resistance value of the non-volatile memory element 100 can be stabilized with lessened non-uniformity. The initial breakdown voltage decreases as the platinum content of the second electrode layer 105 increases, and satisfies a voltage which is not greater than 3.3V used as a general electric power supply voltage source, even when considering non-uniformity in a range in which the platinum content is not less than 20 atm %. That is, by setting the platinum content of the second electrode layer 105 to not less than 20 atm % and not greater than 50 atm %, reduction and non-uniformity of the initial resistance value can be suppressed and the initial breakdown voltage can be lowered.

The values of Young's modulus and thermal expansion coefficients of the precious metals are shown below.

TABLE 1

| | | Thermal | |
|---|---|---|---|
| | Young's | expansion | Melting |
| Precious | modulus | coefficient | point |
| metal | (×10⁹ N/m²) | (degrees C.⁻¹) | (degrees C.) |
| Au | 78.0 | 14.2 × 10⁻⁶ | 1064 |
| Pt | 152 | 8.8 × 10⁻⁶ | 1770 |
| Ag | 82.9 | 18.9 × 10⁻⁶ | 2210 |
| Pd | 110 | 11.8 × 10⁻⁶ | 1550 |
| Rh | 460 | 9.6 × 10⁻⁶ | 1970 |
| Ru | 414 | 6.75 × 10⁻⁶ | 2310 |
| Cu | 130 | 16.5 × 10⁻⁶ | 1085 |
| Ir | 529 | 6.4 × 10⁻⁶ | 2410 |
| Os | 550 | 4.7 × 10⁻⁶ | 3045 |

As illustrated above, among precious metals other than iridium (Ir), precious metals (Au, Pt, Ag, Pd, Rh, Ru, Cu) except for osmium (Os) are lower in Young's modulus and higher in thermal expansion coefficient (lower in melting point) than iridium. Therefore, it is presumed that these precious metals can lower the initial breakdown voltage but are plastically deformed due to heat and a mechanical stress, which causes the hillocks to be formed thereon easily. Therefore, it is presumed that by using the alloy of iridium (Ir) and at least one of the above precious metals (Au, Pt, Ag, Pd, Rh, Ru, Cu), as the electrode material of the second electrode layer 105, the same advantages as those achieved by using the alloy of iridium and platinum (FIG. 3) can be achieved.

[Resistance Changing Characteristic of Non-Volatile Memory Element]

Next, a resistance changing characteristic in a case where the electric pulse is applied to the non-volatile memory element 100 of the present embodiment will be described.

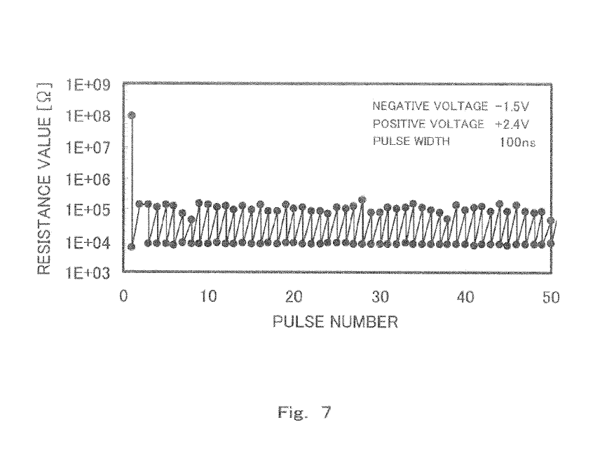

FIG. 7 is a graph showing the relationship between the resistance value of the variable resistance layer 104 and the number of times of pulse application in the non-volatile memory element according to Embodiment 1 of the present invention. The platinum content of the iridium-platinum alloy material constituting the second electrode layer 105 is 50 atm %. FIG. 7 shows a change in the resistance value in the case where two kinds of electric pulses having a pulse width of 100 ns and being different in polarity are applied between the first electrode layer 103 and the second electrode layer 105 alternately.

By applying the two kinds of electric pulses between the electrodes alternately, the resistance value of the variable resistance layer 104 changes reversibly. To be specific, in the example shown in FIG. 7, when a negative voltage pulse (voltage −1.5V, pulse width 100 ns) is applied between the electrodes, the resistance value of the variable resistance layer 104 decreases to 10000Ω (1E+04Ω, lower-resistance value), while when a positive voltage pulse (voltage +2.4V, pulse width 100 ns) is applied between the electrodes, the resistance value of the variable resistance layer 104 increases to 100000Ω (1E+05Ω, higher-resistance value). As defined herein, “positive voltage” is a case where a positive voltage is applied to the second electrode layer 105 on the basis of the first electrode layer 103, while “negative voltage” is a case where a negative voltage is applied to the second electrode layer 105 on the basis of the first electrode layer 103. Hereinafter, the same definition will be used.

The result of FIG. 7 is that of the variable resistance layer 104 having a thickness of about 50 nm (thickness of the second region 107 of the variable resistance layer 104 is 5 nm) and a diameter of 0.5 μm in a pattern. Hereinafter, the variable resistance layer 104 has this size except for cases specially described.

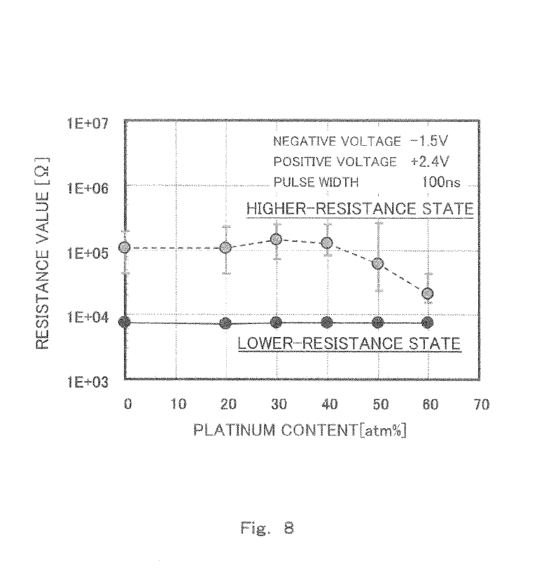

FIG. 8 is a graph showing a change in the resistance value of the variable resistance layer with respect to the platinum content of the second electrode layer. When the platinum content of the iridium-platinum alloy is not greater than 50 atm %, a difference between lower-resistance state (10000Ω) and a higher-resistance state (100000Ω) in the variable resistance layer is great, and therefore the lower-resistance state and the higher-resistance state can be distinguished from each other clearly. However, when the platinum content of iridium-platinum alloy is greater than 50 atm %, the variable resistance layer is unable to maintain the higher-resistance state and has great non-uniformity, which makes the difference between the lower-resistance state and the higher-resistance state smaller. Therefore, it becomes difficult to distinguish between the lower-resistance state and the higher-resistance state from each other clearly.

[Range of Platinum Content]

From the above result of the resistance changing characteristic of the variable resistance layer, the platinum content of the iridium alloy electrode material including platinum, which constitutes the second electrode layer 105, is preferably not less than 20 atm % and not greater than 50 atm %.

As should be clearly understood from the above, the electric characteristics are equivalent between platinum and palladium, the phenomenon of the hillocks shown in FIG. 5 is equivalent between platinum and palladium, and non-uniformity of the initial resistance and the initial breakdown voltage as described with reference to FIG. 6 are equivalent between platinum and palladium. Therefore, it may be presumed that the content of palladium in the case where the second electrode layer 105 comprises the iridium alloy electrode material including palladium is preferably not less than 20 atm % and not greater than 50 atm %, as in the case of the iridium alloy including platinum. The same applies to the above stated another precious metals (Au, Ag, Rh, Ru, Cu).

[Exemplary Operation of Non-Volatile Memory Element]

Next, a description will be given of an exemplary operation of the non-volatile memory element 100 of the present embodiment as a memory, i.e., exemplary operation performed when information is written to/read from the non-volatile memory element 100, with reference to the drawings.

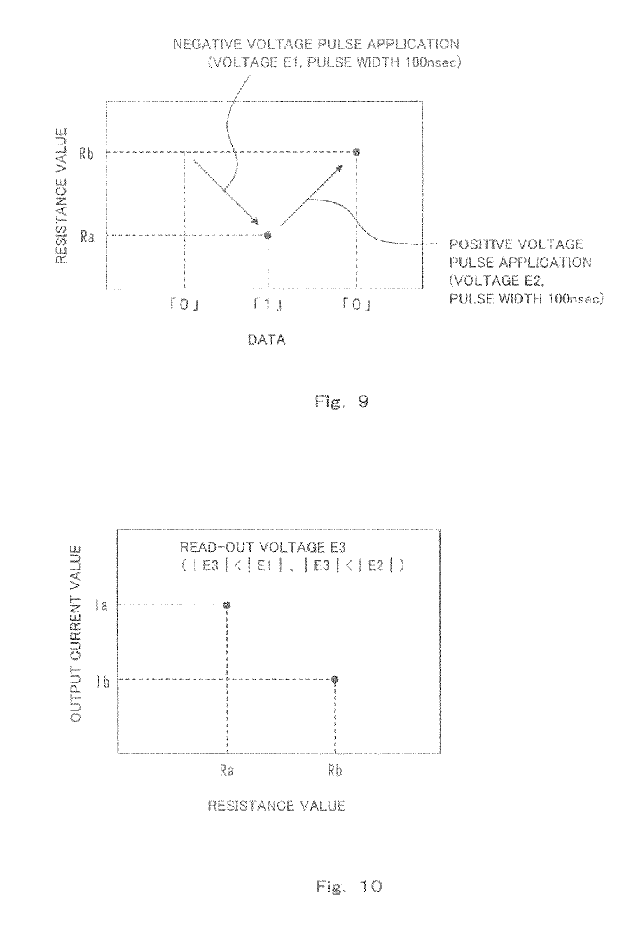

FIG. 9 is a view showing an exemplary operation in a case where data is written to the non-volatile memory element according to Embodiment 1 of the present invention.

As shown in FIG. 9, when two kinds of electric pulses having an amplitude of a predetermined threshold voltage or greater, having a pulse width of 100 ns and being different in polarity are applied between the first electrode layer 103 and the second electrode layer 105 alternately, the resistance value of the variable resistance layer changes. To be specific, when a negative voltage pulse (voltage E1, pulse width 100 ns) is applied between the electrodes, the resistance value of the variable resistance layer decreases from a higher-resistance value Rb to a lower-resistance value Ra. On the other hand, when a positive voltage pulse (voltage E2, pulse width 100 ns) is applied between the electrodes, the resistance value of the variable resistance layer increases from the lower-resistance value Ra to the higher-resistance value Rb. The voltage E1 is, for example, −1.5V, and the voltage E2 is, for example, +2.4V.

In the example shown in FIG. 9, the higher-resistance value Rb is allocated to data “0” and the lower-resistance value Ra is allocated to data “1.” Therefore, the data “0” is written by applying the positive voltage pulse between the electrodes so that the resistance value of the variable resistance layer becomes the higher-resistance value Rb, while the data “1” is written by applying the negative voltage pulse between the electrodes so that the resistance value of the variable resistance layer becomes the lower-resistance value Ra.

FIG. 10 is a view showing an exemplary operation of the non-volatile memory element according to Embodiment 1 of the present invention, which occurs when reading out data.

As shown in FIG. 10, when reading out data, a read-out voltage E3 (|E3|<|E1|, |E3|<|E2|, for example, 0.5V) which has an amplitude much smaller than that of the electric pulse applied to change the resistance value of the variable resistance layer and will not cause resistance change, is applied between the electrodes. As a result, a current corresponding to the resistance value of the variable resistance layer is output, and its output current value is detected, thereby enabling reading out of the written data.

In the example illustrated in FIG. 10, since an output current value Ia corresponds to the resistance value Ra and an output current value Ib corresponds to the resistance value Rb, the data “1” is read out when the output current value Ia is detected, while the data “0” is read out when the output current value Ib is detected.

Since the variable resistance layer serves as a memory section in a region sandwiched between the first electrode layer 103 and the second electrode layer 105, in the manner described above, the non-volatile memory element 100 operates as a memory.

(Modified Example of Embodiment 1)

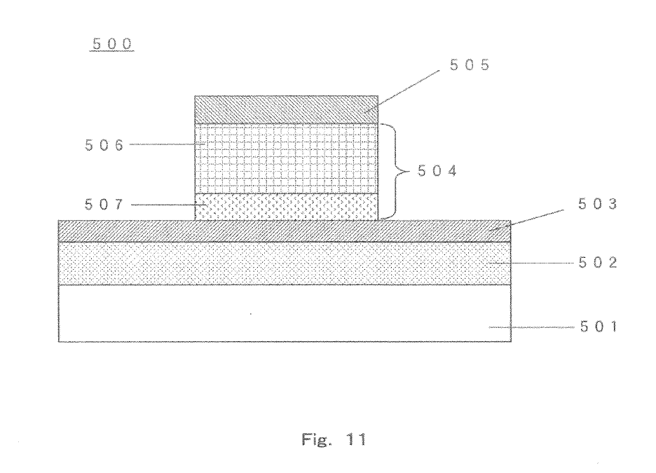

FIG. 11 is a cross-sectional view showing another exemplary configuration of the non-volatile memory element according to Embodiment 1 of the present invention. A non-volatile memory element 500 of the present example is different from the example shown in FIG. 1 in that constituents of the non-volatile memory element are reversed in a vertical direction. To be specific, the non-volatile memory element 500 of FIG. 11 includes an oxide layer 502 formed on a substrate 501, a second electrode layer 503 formed on the oxide layer 502, a variable resistance layer 504 formed on the second electrode layer 503, and a first electrode layer 505 formed on the variable resistance layer 504, and the variable resistance layer 504 includes a first region 506 which is in contact with the first electrode layer 505 and comprises an oxygen-deficient transition metal oxide, and a second region 507 which is in contact with the second electrode layer 505 and comprises a transition metal oxide having a higher oxygen content than the first region 506. The second electrode layer 503 comprises iridium alloy (iridium-platinum alloy) including platinum.

In the present example, the second region 507 cannot be formed by oxidizing the first region 506. Therefore, for example, the second region 507 having a higher oxygen content is deposited in such a manner that a transition metal or a transition metal oxide target is used in reactive sputtering, and an oxygen content in a sputter gas atmosphere is adjusted during the deposition.

(First Application Example of Non-Volatile Memory Element)

The above stated non-volatile memory element of Embodiment 1 is applicable to non-volatile memory devices having various configurations. As a first application example of the non-volatile memory element of the present embodiment, there is a cross-point type non-volatile memory device in which the non-volatile memory element (active layer) intervenes at an intersection (three-dimensional cross point) between a word line and a bit line. Hereinafter, this example will be described.

[Configuration of Non-Volatile Memory Device According to First Application Example]

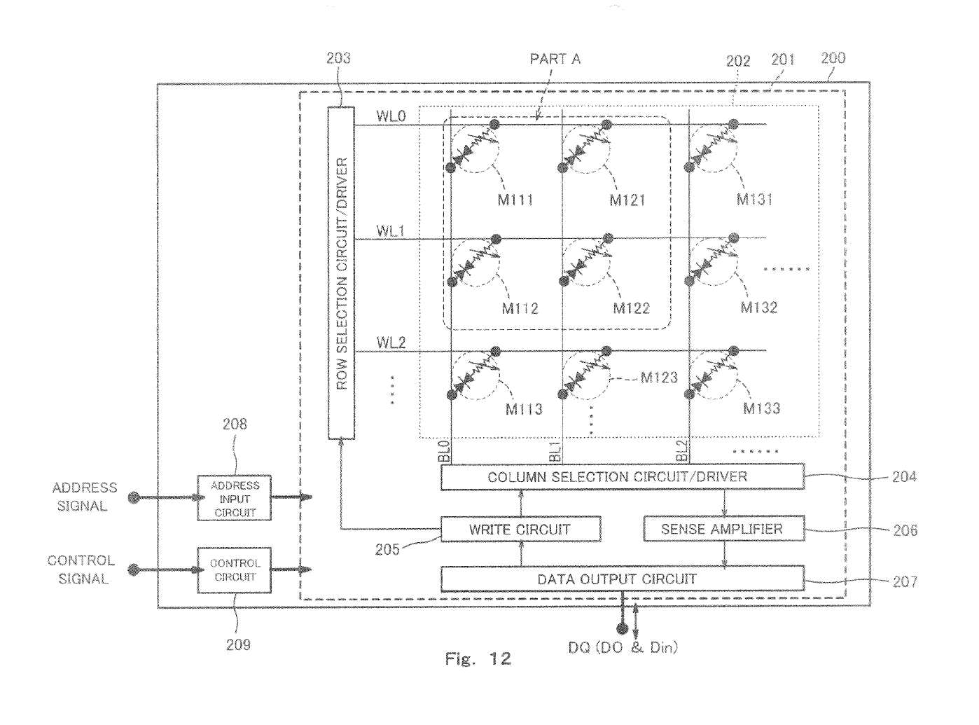

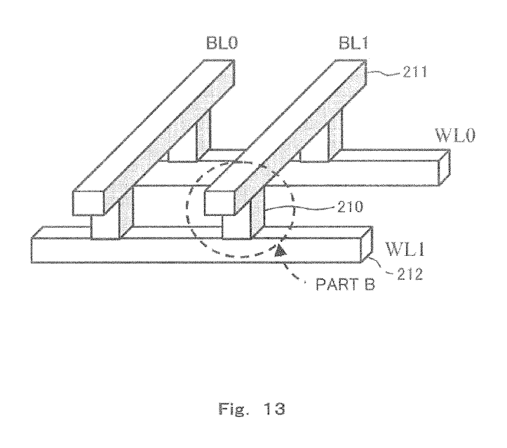

FIG. 12 is a block diagram showing the configuration of a non-volatile memory device in the first application example incorporating the non-volatile memory element according to Embodiment 1 of the present invention. FIG. 13 is a perspective view showing the configuration (configuration of 4 bits) of a part A in the non-volatile memory device of FIG. 12.

As shown in FIG. 12, a non-volatile memory device 200 according to the present example includes a memory main body 201 on a semiconductor substrate. The memory main body 201 includes a memory array 202, a row selection circuit/driver 203, a column selection circuit/driver 204, a write circuit 205 for writing data, a sense amplifier 206 which detects an amount of a current flowing in a selected bit line and determines the data as “1” or “0” and a data input/output circuit 207 which executes input/output process of input/output data via a terminal DQ. The non-volatile memory device 200 further includes an address input circuit 208 which receives an address signal externally input, and a control circuit 209 for controlling the operation of the memory main body 201, based on a control signal externally input.

As shown in FIGS. 12 and 13, the memory array 202 includes a plurality of word lines (first wires) WL0, WL1, WL2, . . . which are formed to extend in parallel with each other on the semiconductor substrate, and a plurality of bit lines (second wires) BL0, BL1, BL2, . . . which are formed above the plurality of word lines WL0, WL1, WL2, . . . , so as to extend in parallel with each other within a plane parallel to a main surface of the semiconductor substrate and so as to three-dimensionally cross the plurality of word lines WL0, WL1, WL2, . . . .

Further, a plurality of memory cells M111, M112, M113, M121, M122, M123, M131, M132, M133, . . . (hereinafter referred to as “memory cells M111, M112, . . . ”) are provided in matrix so as to respectively correspond to the three-dimensional cross points of the plurality of word lines WL0, WL1, WL2, . . . , and the plurality bit lines BL0, BL1, BL2 . . . .

Each of the memory cells M111, M112, . . . includes the non-volatile memory element 100 of Embodiment 1 and a current controlling element connected in series to the non-volatile memory element 100. Each non-volatile memory element includes the variable resistance layer having the stacked layer structure and comprising the oxygen-deficient transition metal oxide.

The memory cells M111, M112, . . . shown in FIG. 12 are identified by reference symbol 210 in FIG. 13.

[Configuration of Non-Volatile Memory Element of Non-Volatile Memory Device according to the First Application Example]

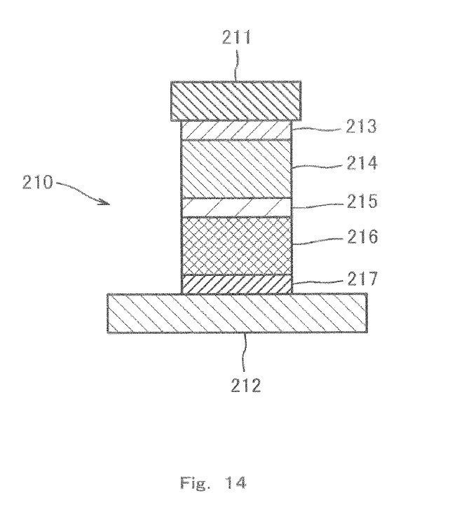

FIG. 14 is a cross-sectional view showing the configuration of the non-volatile memory element in the first application example of the non-volatile memory device of FIG. 12. In FIG. 14, the configuration of part B of FIG. 13 is shown.

As shown in FIG. 14, in the non-volatile memory device of the present application example, a non-volatile memory element 210 is interposed between a lower wire 212 (corresponding to word line WL1 in FIG. 13) which is a copper wire and an upper wire 211 (corresponding to a bit line BL1 in FIG. 13) which is a copper wire, and includes a lower electrode 217, a current controlling layer 216, an inner electrode 215, a variable resistance layer 214, and an upper electrode 213 which are stacked together in this order.

The inner electrode 215, the variable resistance layer 214, and the upper electrode 213 correspond to the first electrode layer 103, the variable resistance layer 104 and the second electrode layer 105 in the non-volatile memory element 100 of Embodiment 1 shown in FIG. 1, respectively. Therefore, the configuration of the present application example is formed like the configuration of Embodiment 1.

The upper electrode 213 formed in contact with the variable resistance layer 214 comprises iridium alloy including platinum. Thus, it is possible to implement the non-volatile memory element which can reduce the voltage of the electric pulse required for the initial breakdown and lessen non-uniformity of the resistance value of the non-volatile memory element.

The current controlling element 216 is connected in series to the variable resistance layer 214 via the inner electrode 215 comprising TaN, The current controlling layer 216 is electrically connected to the variable resistance layer 214. The current controlling element composed of the lower electrode 217, the current controlling layer 216, and the inner electrode 215 is an element typified by an MIM (Metal-Insulator-Metal) diode or an MSM (Metal-Semiconductor-Metal) diode, and has a nonlinear current characteristic with respect to a voltage. The MSM diode is capable of flowing a more current. As the current controlling layer 216, nitrogen-deficient silicon nitride (SiNₓ), an amorphous Si, etc., may be used. In addition, the current controlling element has a bidirectional current characteristic with respect to a voltage, and is configured to be placed in a conductive state under a predetermined threshold voltage Vf (for example, +IV or more, or −1V or less based on one electrode as a reference).

Tantalum and its oxide are materials generally used for the semiconductor process steps, and have a very high compatibility with the semiconductor process steps. Therefore, these materials can be easily incorporated in the existing semiconductor manufacturing process steps.

[Example of Configuration of Multilayer-Structure Non-Volatile Memory Device]

It is possible to attain a multilayer-structure non-volatile memory device by three-dimensionally stacking the memory arrays of the non-volatile memory device according to the present application example of FIGS. 12 and 13.

FIG. 15 is a perspective view showing the configuration of a memory array in a multi-layer structure of the first application example of the non-volatile memory device of FIG. 12. As shown in FIG. 15, this non-volatile memory device includes a multi-layer memory array obtained by stacking a plurality of memory arrays together, each memory array comprising a plurality of lower wires (first wires) 212 which are formed to extend in parallel with each other on the semiconductor substrate (not shown), a plurality of upper wires (second wires) 211 which are formed above the plurality of lower wires 212 so as to extend in parallel with each other within a plane parallel to the main surface of the semiconductor substrate, and so as to three-dimensionally cross the plurality of lower wires 212, and a plurality of memory cells 210 which are disposed in matrix to respectively correspond to the three-dimensional cross-points between the plurality of lower wires 212 and the plurality of upper wires 211.

While in the example shown in FIG. 15 there are provided five wire layers and four layers of non-volatile memory elements disposed at the three-dimensional cross-points of the wire layers, it is a matter of course that the numbers of these layers and elements may be increased or decreased as desired.

An ultra-high capacity non-volatile memory is attainable by providing the multi-layer memory arrays thus configured.

As already described in Embodiment 1, the variable resistance layer of the present invention can be formed at a low temperature. Therefore, even when the layer structure is formed in the wiring process as shown in the present embodiment, transistors or wire material such as silicide formed in the lower-layer step are not affected, and therefore, the multi-layer memory array can be easily attained. That is, the multi-layer structure non-volatile memory device can be easily attained by using the variable resistance layer including the tantalum oxide according to the present invention.

[Second Application Example of Non-Volatile Memory Element]

As a second application example of the non-volatile memory element of the present embodiment, there is a non-volatile memory device having a structure of one transistor-one non-volatile memory element (1T1R configuration).

[Configuration of Non-Volatile Memory Device According to Second Application Example]

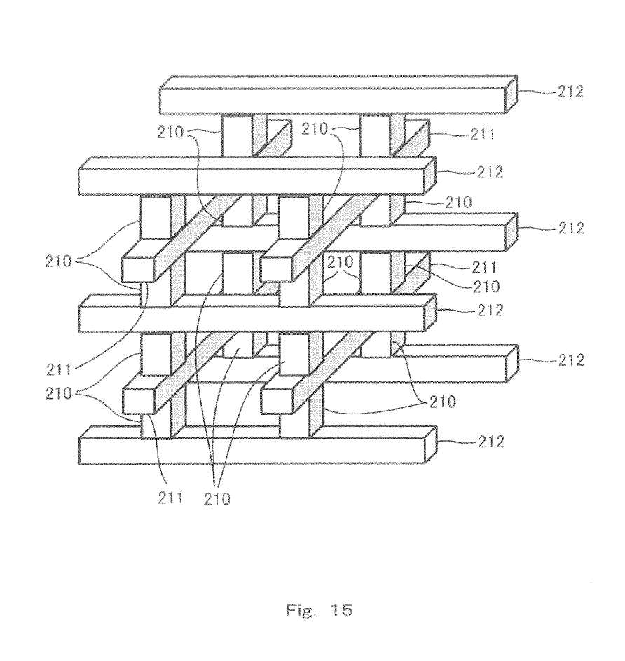

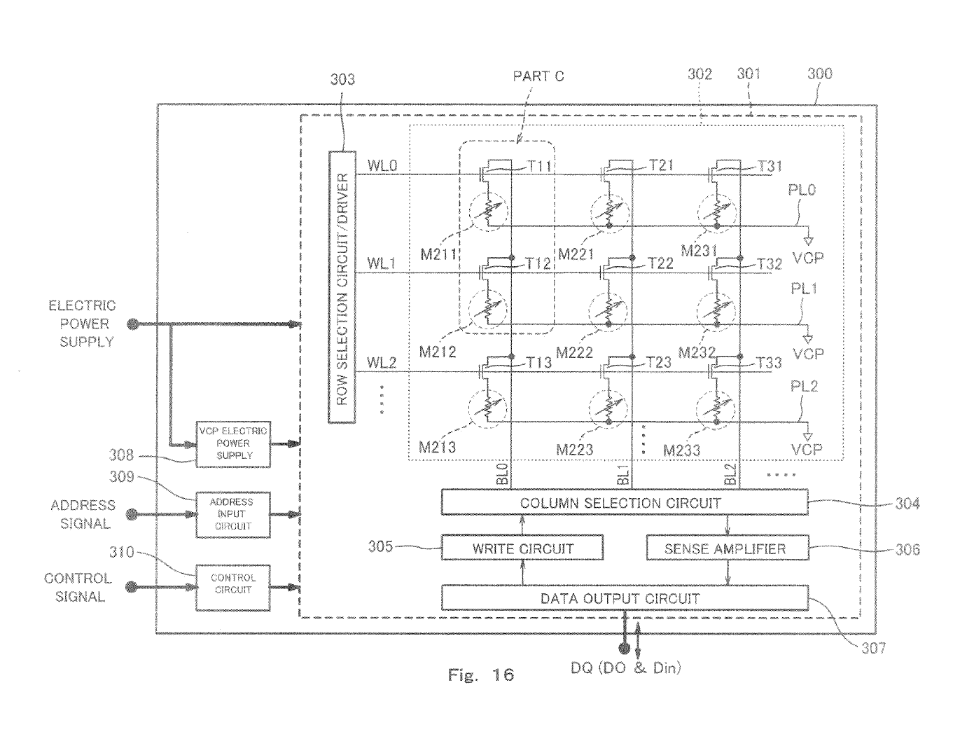

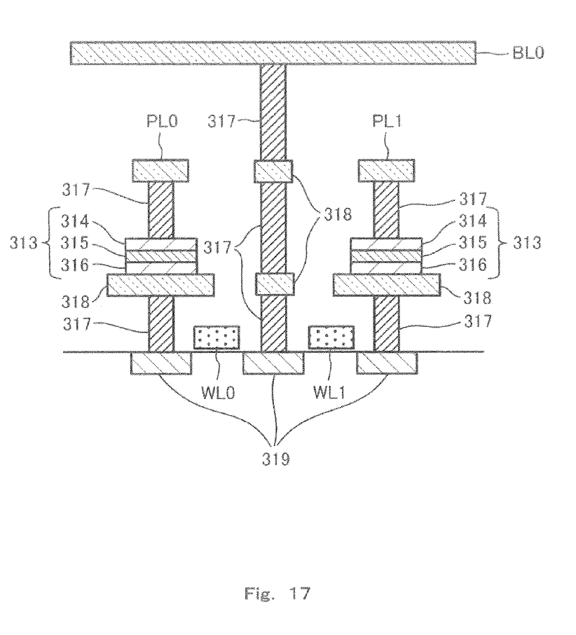

FIG. 16 is a block diagram showing the configuration of the second application example of the non-volatile memory device incorporating the non-volatile memory element according to Embodiment 1 of the present invention. FIG. 17 is a cross-sectional view showing the configuration (configuration of 2 bits) of a part C in the non-volatile memory device of FIG. 12.

As shown in FIG. 16, a non-volatile memory device 300 according to the present application example includes a memory main body 301 on a semiconductor substrate. The memory main body 301 includes a memory array 302, a row selection circuit/driver 303, a column selection circuit 304, a write circuit 305 for writing data, a sense amplifier 306 for detecting an amount of a current flowing in a selected bit line and determines the data as “1” or “0,” and a data input/output circuit 307 for performing input/output processing of input/output data via the terminal DQ. The non-volatile memory device 300 further includes a cell plate electric power supply (VCP electric power supply) 308, an address input circuit 309 which receives an address signal externally input, and a control circuit 310 for controlling the operation of the memory main body 301, based on a control signal externally input.

The memory array 302 includes the plurality of word lines (first wires) WL0, WL1, WL2, . . . and the plurality of bit lines (second wires) BL0, BL1, BL2, . . . which are formed on the semiconductor substrate and are arranged to three-dimensionally cross each other, a plurality of transistors T11, T12, T13, T21, T22, T23, T31, T32, T33, . . . (hereinafter expressed as “transistors T11, T12, . . . ”) provided to respectively correspond to intersections of the word lines WL0, WL1, WL2, . . . and the bit lines BL0, BL1, BL2, . . . , and a plurality of memory cells M211, M212, M213, M221, M222, M223, M231, M232, N233 (hereinafter expressed as “memory cells M211, M212, . . . ” provided to respectively correspond to the transistors T11, T12, . . . in a one-to-one correspondence.

The memory array 302 further includes a plurality of plate lines (third wires) PL0, PL1, PL2, . . . which are arranged to extend in parallel with the word lines WL0, WL1, WL2, . . . As shown in FIG. 17, the bit line BL0 is disposed above the word lines WL0, WL1, and the plate lines PL0, PL1 are disposed between the word lines WL0, WL1 and the bit line BL0.

Each of the memory cells M211, M212, . . . corresponds to the non-volatile memory element 100 according to Embodiment 1, and includes a variable resistance layer having the stacked-layer structure comprising oxygen-deficient transition metal oxides. To be specific, a non-volatile memory element 313 in FIG. 17 corresponds to the memory cells M211, M212, . . . in FIG. 16, and includes an upper electrode 314, a variable resistance layer 315 having the stacked-layer structure comprising the oxygen-deficient transition metal oxides, and a lower electrode 316. One of the upper electrode 314 and the lower electrode 316 comprises the iridium alloy (iridium-platinum alloy) including platinum. Thus, it is possible to implement the non-volatile memory element which can reduce the voltage of the electric pulse required for the initial breakdown and lessen non-uniformity of the resistance value of the non-volatile memory element.

In FIG. 17, 317 denotes a plug layer, 318 denotes a metal wire layer, and 319 denotes source/drain region.

As shown in FIG. 16, drains of the transistors T11, T12, T13, . . . are connected to the bit line BL0, drains of the transistors T21, T22, T23, . . . are connected to the bit line BL1, and drains of the transistors T31, T32, T33, . . . are connected to the bit line BL2.

Gates of the transistors T11, T21, T31, . . . are connected to the word line WL0, gates of the transistors T12, T22, T32, . . . are connected to the word line WL1, and gates of the transistors T13, T23, T33, . . . are connected to the word line WL2.

Sources of the transistors T11, T12, . . . are connected to the memory cells M211, M212, . . . , respectively.

The memory cells M211, M221, M231, . . . are connected to the plate line PL0, the memory cells M212, M222, M232, . . . are connected to the plate line PL1, and the memory cells M213, M223, M233, . . . are connected to the plate line PL2.

The address input circuit 309 receives an address signal from an external circuit (not shown), and outputs a row address signal and a column address signal to the row selection circuit/driver 303 and the column selection circuit 304, respectively, based on the address signal. The address signal is a signal indicating the address of a particular memory cell to be selected from among the plurality of memory cells M211, M212, . . . The row address signal is a signal indicating the address of a row in the address indicated by the address signal, and the column address signal is a signal indicating the address of a column in the address indicated by the address signal.

In a data write cycle, the control circuit 310 outputs to the write circuit 305, a write signal for causing application of a write voltage, according to input data Din input to the data input/output circuit 307. On the other hand, in a data readout cycle, the control circuit 310 outputs to the column selection circuit 304, a readout signal for causing application of a readout voltage.

The row selection circuit/driver 303 receives the row address signal output from the address input circuit 309, selects any one from among the plurality of word lines WL0, WL1, WL2, . . . according to the row address signal, and applies a predetermined voltage to the selected word line.

The column selection circuit 304 receives a column address signal output from the address input circuit 309, selects any one from among the plurality bit lines BL0, BL1, BL2, according to the column address signal, and applies the write voltage or the readout voltage to the selected bit line.

Receiving the write signal output from the control circuit 310, the write circuit 305 outputs to the column selection circuit 304, a signal for causing application of the write voltage to the selected bit line.

In the data readout cycle, the sense amplifier 306 detects an amount of a current flowing in the selected bit line which is a readout target, and determines the data as “1” or “0.” The resulting output data DO is output to the external circuit via the data input/output circuit 307.

In the present application example using the configuration of one transistor-one non-volatile memory element, a storage capacity is smaller than that of the configuration using the cross-point type non-volatile memory element in the first application example. However, the present application example may dispense with the current controlling element such as the diode, and therefore is advantageously easily combined with a CMOS process. In addition, operation control for the present application example is advantageously easier.

As in the first application example, the variable resistance layer of the present invention can be formed at a low temperature. Therefore, it is advantageous that transistors or wire material such as silicide formed in a lower layer step are not affected even when a layer structure is formed in a wiring step illustrated in this embodiment.

Furthermore, as in the case of the first application example, since deposition of tantalum and its oxide are easily incorporated into the existing semiconductor manufacturing process steps, the non-volatile memory device of the present application example can be easily manufactured.

[Measurement Result of Non-Volatile Memory Device in Second Application Example]

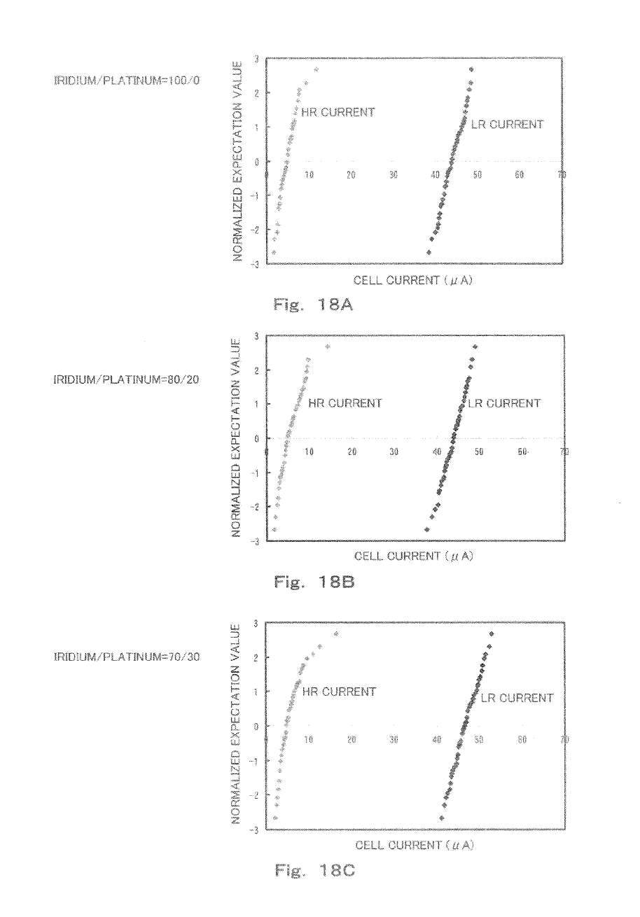

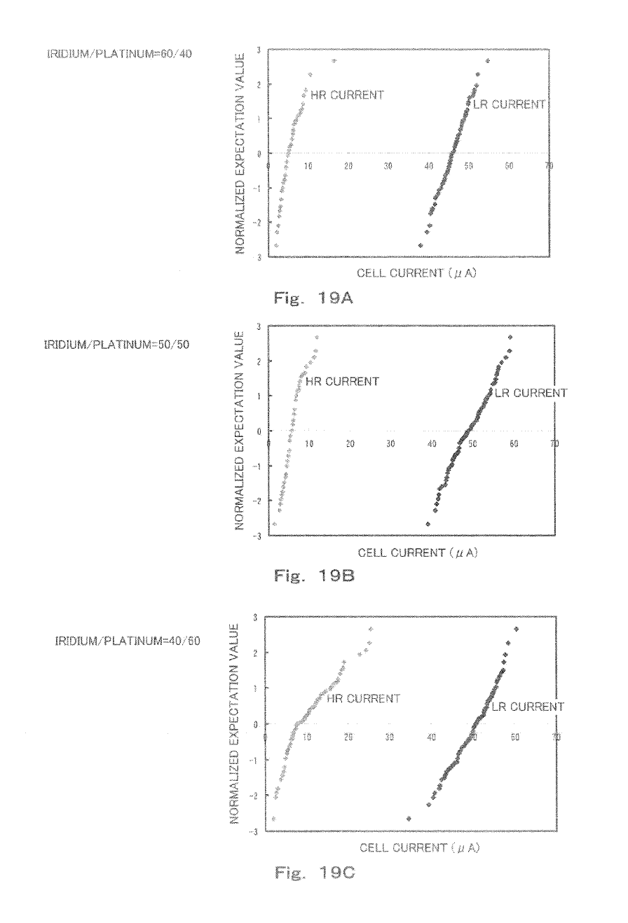

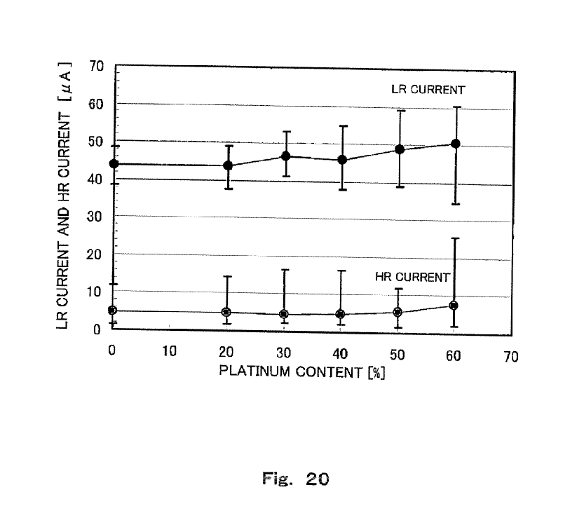

The resistance changing characteristic of the non-volatile memory element including a variable resistance layer and a transistor in a non-volatile memory device in the present application example was measured, and a dependency of the second electrode layer on the platinum content was reviewed. FIGS. 18A to 18C and FIGS. 19A to 19C are normalized expectation value distribution graphs each showing an evaluation result of a cell current flowing through the non-volatile memory element of the non-volatile memory device in the second application example. FIG. 20 is a graph showing a change in the cell current with respect to a change in the platinum content of the second electrode layer, in the non-volatile memory of the non-volatile memory device in the second application example. In the graphs of FIGS. 18A to 18C and FIGS. 19A to 19C, a greater inclination with respect to a vertical direction indicates that the degree of non-uniformity of the cell current is greater (non-volatile memory is unable to operate favorably), while a smaller inclination with respect to the vertical direction indicates that the degree of non-uniformity of the cell current is less (non-volatile memory is able to operate favorably). In the examples shown in FIGS. 18A to 18C and FIGS. 19A to 19C, a transistor of 1.8V and a gate width of 0.44 μm was used, and a pulse of 1.8V was applied after the initial breakdown process in a design circuit to stabilize the resistance changing characteristic. As shown in FIGS. 18A to 18C and FIGS. 19A and 19B, it could be confirmed that in a range in which the platinum content was not greater than 50 atm %, a favorable operation could be confirmed regarding a current value (LR current value) corresponding to a lower-resistance state and a current value (HR current value) corresponding to a higher-resistance state. By comparison, as shown in FIG. 19C, it was confirmed that in the case of the element in which the platinum content was 60 atm %, the degrees of non-uniformity of both of the LR current value and the HR current value increased.

FIG. 20 is a graph showing a change in the cell current with respect to a change in the platinum content of the second electrode layer, in the non-volatile memory element of the non-volatile memory device in the second application example. As shown in FIG. 20, it was confirmed that when the platinum content of the second electrode layer was 60 atm %, a difference (window) between a minimum value of the LR current value and a maximum value of the HR current value decreased. Such a small widow is unfavorable because this may lead to misdetermination which would occur when the resistance value is read.

From the above results, it was suggested that the platinum content was not greater than 50 atm %, to manufacture the non-volatile memory element having lessened non-uniformity.

Although in the above embodiment, the transition metal oxide layer has the stacked-layer structure of the tantalum oxide, for example, the stacked-layer structure of the hafnium (Hf) oxide or the stacked-layer structure of the zirconium (Zr) oxide may be used.

In the case of using the stacked-layer structure of the hafnium oxide, preferably, 0<x<2.0 and x<y are satisfied when a first region of the stacked-layer structure is HfOₓ and the second region of the stacked-layer structure is HfO_{y}, and the thickness of the second hafnium oxide is not less than 3 nm and not greater than 4 nm.

In the case of using the stacked-layer structure of the zirconium oxide, preferably, 0<x<2.0 and x<y are satisfied when a first region of the stacked-layer structure is ZrOₓ and a second region of the stacked-layer structure is ZrO_{y}, and the thickness of the second region is not less than 1 nm and not greater than 5 nm.

In the case of the hafnium oxide, the first region is deposited on the lower electrode by a reactive sputtering method for performing sputtering in argon gas and oxygen gas using the Hf target. The second region can be formed in such a manner that the surface of the first region is exposed to plasma of the argon gas and the oxygen gas after forming the first region. The oxygen content of the first region can be adjusted more easily by changing a flow ratio of the oxygen gas with respect to the argon gas during the reactive sputtering, as in the case of the above stated tantalum oxide. The substrate temperature may be a room temperature without special heating.

In the case where the first region comprises the hafnium oxide, the thickness of the first region can be adjusted more easily depending on a time for which it is exposed to the plasma of the argon gas and the oxygen gas. When the composition of the first region is expressed as HfOₓ and the composition of the second region is expressed as HfO_{y}, a stable resistance changing characteristic can be attained under the conditions in which 0.9×1.6 and 1.8<y<2.0 are satisfied, and the thickness of the second region is not less than 3 nm and not greater than 4 nm.

In the case of the zirconium oxide, the first region is deposited on the lower electrode by the reactive sputtering method for performing sputtering in argon gas and oxygen gas using the Zr target. The second region can be formed in such a manner that the surface of the first region is exposed to the plasma of the argon gas and the oxygen gas after forming the first region. The oxygen content of the first region can be adjusted more easily by changing a flow ratio of the oxygen gas with respect to the argon gas during the reactive sputtering, as in the case of the above stated tantalum oxide. The substrate temperature may be a room temperature without special heating.

In the case of the zirconium oxide, the thickness of the second region can be adjusted more easily depending on a time for which it is exposed to the plasma of the argon gas and the oxygen gas. When the composition of the first region is expressed as ZrOₓ and the composition of the second region is expressed as ZrO_{y}, a stable resistance changing characteristic can be attained under the conditions in which 0.9≦x≦1.4 and 1.9<y<2.0 are satisfied, and the thickness of the second region is not less than 1 nm and not greater than 5 nm.

Although in the above described embodiments, the tantalum oxide, the hafnium oxide and the zirconium oxide are described as the transition metal oxide used as the variable resistance layer, the transition metal oxide layer sandwiched between the first electrode and the second electrode may be any layer so long as the oxide layer of tantalum, hafnium, zirconium, etc., is included in that layer as a primary variable resistance layer which performs a resistance changing operation, and another elements of a small amount may be included in the transition metal oxide layer. Another elements may be added intentionally for the purpose of fine adjustment of the resistance value. Such a case is included in the scope of the present invention. For example, if nitrogen is added to the variable resistance layer, the resistance value of the variable resistance layer increases, and reactivity of the resistance change can be improved.

When the variable resistance layer is deposited by sputtering, elements of a small amount may be mixed into the variable resistance layer unexpectedly due to remaining gas and gas release from a vacuum container wall. The case where the elements of a small amount is mixed into a resistive layer is included in the scope of the present invention, of course.

Numerous modifications and alternative embodiments of the invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention.

### INDUSTRIAL APPLICABILITY

The present invention provides a variable resistance semiconductor memory element and a non-volatile memory device including the variable resistance semiconductor memory element, and implements a non-volatile memory element which is highly reliable and is capable of performing a stable operation. Therefore, the present invention is useful in electronic devices incorporating the non-volatile memory.

### REFERENCE SIGNS LISTS

100 non-volatile memory element
101 substrate
102 oxide layer
103 first electrode layer (first electrode)
104 variable resistance layer
105 second electrode layer (second electrode)
106 first region (variable resistance layer)
107 second region (variable resistance layer)
200 non-volatile memory device
201 memory main body
202 memory array
203 row selection circuit/driver
204 column selection circuit/driver
205 write circuit
206 sense amplifier
207 data input/output circuit
208 address input circuit
209 control circuit
210 non-volatile memory element
211 upper wire
212 lower wire
213 upper electrode
214 variable resistance layer
215 inner electrode
216 current controlling element
217 lower electrode
218 ohmic resistance layer
219 second variable resistance layer
300 non-volatile memory device
301 memory main body
302 memory array
303 row selection circuit/driver
304 column selection circuit
305 write circuit
306 sense amplifier
307 data input/output circuit
308 cell plate electric power supply
309 address input circuit
310 control circuit
313 non-volatile memory element
314 upper electrode
315 variable resistance layer
316 lower electrode
BL0, BL1, . . . bit lines
M11, M12, memory cells
T11, T12, . . . transistors
WL0, WL1, . . . word lines
500 non-volatile memory element
501 substrate
502 oxide layer
503 second electrode layer
504 variable resistance layer
505 first electrode layer
506 first region
507 second region

1-7. (canceled)

8. A non-volatile memory element comprising:
a first electrode;
a second electrode; and
a variable resistance layer interposed between the first electrode and the second electrode, a resistance value of the variable resistance layer being changeable reversibly in response to an electric signal applied between the first electrode and the second electrode;
wherein the variable resistance layer includes a first region which is in contact with the first electrode and comprises an oxygen-deficient transition metal oxide and a second region which is in contact with the second electrode and comprises a transition metal oxide having a smaller degree of oxygen deficiency than the first region; and
the second electrode comprises an alloy including iridium and at least one precious metal having lower Young's modulus than iridium, and a content of iridium is not less than 50 atm %; and
the alloy allows a voltage of an electric pulse required for initial breakdown of the variable resistance layer to be reduced, and non-uniformity of the resistance value of the non-volatile memory element to be lessened.

9. The non-volatile memory element according to claim 8,
wherein the second electrode comprises an alloy including iridium and platinum, and a content of platinum is not less than 20 atm % and not greater than 50 atm %.

10. The non-volatile memory element according to claim 8,
wherein the second electrode comprises an alloy including iridium and palladium, and a content of palladium is not less than 20 atm % and not greater than 50 atm %.

11. The non-volatile memory element according to claim 8,
wherein the variable resistance layer has a stacked-layer structure in which the transition metal oxide constituting the variable resistance layer is composed of a plurality of layers which are different in oxygen concentration.

12. A non-volatile semiconductor device comprising:
a memory array including:
a plurality of first wires formed on a semiconductor substrate such that the plurality of first wires extend in parallel with each other;
a plurality of second wires formed above the plurality of first wires such that the plurality of second wires extend in parallel with each other within a plane parallel to a main surface of the semiconductor substrate and three-dimensionally cross the plurality of first wires, respectively; and
non-volatile memory elements provided to respectively correspond to three-dimensional cross points of the plurality of first wires and the plurality of second wires; wherein
each of the non-volatile memory elements includes:
a first electrode;
a second electrode; and
a variable resistance layer interposed between the first electrode and the second electrode, a resistance value of the variable resistance layer being changeable reversibly in response to an electric signal applied between the first electrode and the second electrode;
the variable resistance layer includes a first region which is in contact with the first electrode and comprises an oxygen-deficient transition metal oxide and a second region which is in contact with the second electrode and comprises an oxygen-deficient transition metal oxide having a smaller degree of oxygen deficiency than the first region; and
the second electrode comprises an alloy including iridium and at least one precious metal having lower Young's modulus than iridium, and a content of iridium is not less than 50 atm %; and
the alloy allows a voltage of an electric pulse required for initial breakdown of the variable resistance layer to be reduced, and non-uniformity of the resistance value of the non-volatile memory element to be lessened.

13. A non-volatile semiconductor device comprising:
a plurality of first wires formed on a semiconductor substrate such that the plurality of first wires extend in parallel with each other;
a plurality of second wires formed above the plurality of first wires such that the plurality of second wires extend in parallel with each other within a plane parallel to a main surface of the semiconductor substrate and three-dimensionally cross the plurality of first wires, respectively;
a plurality of third wires arranged in parallel with the plurality of first wires or the plurality of second wires such that the plurality of third wires extend in parallel with each other;
a plurality of transistors provided to respectively correspond to three-dimensional cross-points of the first wires and the second wires; and
a plurality of non-volatile memory elements provided to respectively correspond to the transistors in a one-to-one correspondence; wherein
each of the non-volatile memory elements includes a first electrode; a second electrode; and a variable resistance layer interposed between the first electrode and the second electrode, a resistance value of the variable resistance layer being changeable reversibly in response to an electric signal applied between a corresponding one of the first wires and a corresponding one of the third wires and thereby applied between the first electrode and the second electrode via a corresponding one of the transistors;
one of the first electrode and the second electrode of the non-volatile memory element is connected to one of a source and a drain of a corresponding one of the transistors;
a gate of each of the plurality of transistors is connected to a corresponding one of the first wires;
the other of the first electrode and the second electrode of the non-volatile memory element is connected to one of a corresponding one of the second wires and a corresponding one of the third wires;
the other of the source and the drain of the transistor is connected to the other of the corresponding one of the second wires and the corresponding one of the third wires;
the variable resistance layer includes a first region which is in contact with the first electrode and comprises an oxygen-deficient transition metal oxide and a second region which is in contact with the second electrode and comprises an oxygen-deficient transition metal oxide having a smaller degree of oxygen deficiency than the first region; and
the second electrode comprises an alloy including iridium and at least one precious metal having lower Young's modulus than iridium, and a content of iridium is not less than 50 atm %; and
the alloy allows a voltage of an electric pulse required for initial breakdown of the variable resistance layer to be reduced, and non-uniformity of the resistance value of the non-volatile memory element to be lessened.

14. The non-volatile memory element according to claim 8, wherein a standard electrode potential of an electrode material of the first electrode is lower than a standard electrode potential of an electrode material of the second electrode.
